(19) United States
(12) Patent Application Publication
(10) Pub. No.: US 2009/0268765 A1
(43) Pub. Date: Oct. 29, 2009

(54) Intra-Cavity Phase Modulated Laser Based on Intra-Cavity Depletion-Edge-Translation Lightwave Modulators

(76) Inventors: Daniel Mahgerefteh, Palo Alto, CA (US); Hongmin Chen, Mountain View, CA (US); Yasuhiro Matsui, Woburn, MA (US)

Correspondence Address: JOHN S. PRATT, ESQ;KILPATRICK STOCKTON, LLP, 1100 PEACHTREE STREET, SUITE 2800, ATLANTA, GA, 30309, US

(21) Appl. No.: 12/110,572

(22) Filed: Apr. 28, 2008

(51) Int. Cl. H01S 5/06

(52) U.S. Cl. 372/28

(57) ABSTRACT

Use of depletion edge translation as an in cavity phase modulation mechanism in lasers. Aspects of the invention are especially relevant (without limitation) in transmitters for extended reach comprising an intra cavity phase and amplitude modulated laser for generation of a frequency modulated signal and a passive optical spectrum reshaper element, sometimes referred to as a chirp modulated laser. Such techniques may be carried out as disclose herein by adopting predetermined doping profiles and applying predetermined voltage to the laser cavity, and more preferably to a phase section in or adjoining the laser cavity.

### FIELD OF THE INVENTION

This invention generally relates to semiconductor laser diodes used in optical fiber communication systems, and more particularly to frequency modulated laser diodes for coding data being transmitted within such fiber optic communication systems, including chirp-managed directly modulated lasers.

### BACKGROUND

U.S. patent application Ser. No. 11/787,163, filed on Apr. 13, 2007 by Yasuhiro Matsui et al. for OPTICAL FM SOURCE BASED ON INTRA-CAVITY PHASE AND AMPLITUDE MODULATION IN LASERS, which is hereby incorporated herein by reference, discloses a transmitter for extended reach comprising an intra-cavity phase and amplitude modulated laser for generation of a frequency modulated signal and a passive optical spectrum reshaper element. This system is sometimes called a chirp managed laser (CML).

In addition, various chirp managed laser systems have been disclosed where the use of a frequency modulated laser source and an optical spectrum reshaper element substantially improves bit error rate performance in an optical fiber transmission system. See, for example:
(1) U.S. patent application Ser. No. 11/272,100, filed Nov. 8, 2005 by Daniel Mahgerefteh et al. for POWER SOURCE FOR A DISPERSION COMPENSATION FIBER OPTIC SYSTEM (Attorney's Docket No. TAYE-59474-00006 CON);
(2) U.S. patent application Ser. No. 10/308,522, filed Dec. 3, 2002 by Daniel Mahgerefteh et al. for HIGH-SPEED TRANSMISSION SYSTEM COMPRISING A COUPLED MULTI-CAVITY OPTICAL DISCRIMINATOR (Attorney's Docket No. TAYE-59474-00007);
(3) U.S. patent application Ser. No. 11/441,944, filed May 26, 2006 by Daniel Mahgerefteh et al. for FLAT DISPERSION FREQUENCY DISCRIMINATOR (FDFD) (Attorney's Docket No. TAYE-59474-00009 CON);
(4) U.S. patent application Ser. No. 11/037,718, filed Jan. 18, 2005 by Yasuhiro Matsui et al. for CHIRP MANAGED DIRECTLY MODULATED LASER WITH BANDWIDTH LIMITING OPTICAL SPECTRUM RESHAPER (Attorney's Docket No. TAYE-26);
(5) U.S. patent application Ser. No. 11/068,032, filed Feb. 28, 2005 by Daniel Mahgerefteh et al. for OPTICAL SYSTEM COMPRISING AN FM SOURCE AND A SPECTRAL RESHAPING ELEMENT (Attorney's Docket No. TAYE-31); and
(6) U.S. patent application Ser. No. 11/084,630, filed Mar. 18, 2005 by Daniel Mahgerefteh et al. for FLAT-TOPPED CHIRP INDUCED BY OPTICAL FILTER EDGE (Attorney's Docket No. TAYE-34).
   Each of the above-identified patent applications are hereby incorporated herein by reference.

Other references which disclose aspects of laser technology which may be relevant to at least some aspects or embodiments of the present invention are the following, which are all incorporated by this reference:
(1) J. G. Mendoza-Alvarez, L. A. Coldren, A. Alping, R. H. Yan, T. Hausken, K. Lee, and K. Pedrotti, Analysis of depletion edge translation lightwave modulators, Journal of Lightwave Technology. Vol. 6, No. 6, June 1988, pp. 793-808;

(2) Jean-Franqoisi Vinchant, Jean Aristide Cavaillks, Marko Erman, Philippe Jarry, and Monique Renaud, InP/GalnAsP Guided-Wave Phase Modulators Based on Carrier-Induced Effects: Theory and Experiment, Journal of Lightwave Technology, Vol. 6, No. 6, January 1992, pp. 63-70; and

(3) R. Laroy et al., “Direct Modulation of Widely Tunable Twin-Guide Lasers,” IEEE Photonics Technology Letters, Vol. 18, No. 12, Jun. 15, 2006.

Certain embodiments of the present invention can be applied to a variety of laser designs having at least a gain section, a phase section and a tuning section. These include distributed Bragg reflector (DBR) lasers, sampled grating distributed Bragg reflector lasers (SG-DBR), modulated grating Y branch distributed Bragg reflector lasers (MGY), as well as vertically integrated lasers such as twin-guided distributed feed-back lasers.

### SUMMARY

Certain embodiments of the present invention provide optical frequency modulated (FM) sources based on intra-cavity phase modulation using the depletion edge translation effect. In one embodiment of the present invention, these sources may be advantageously used in conjunction with a chirp managed laser (CML). In addition, several new laser designs and constructs are presented for maximizing the FM efficiency of such lasers for the CML application. These laser constructs generally comprise a gain section, a tuning section such as a Bragg grating, and one or more phase modulation sections. In an embodiment of the present invention, at least one of the phase modulation sections is directly modulated with a digital data signal and is properly designed, as described more fully herein, to generate a substantial phase shift of the laser signal upon each passage in the laser cavity, causing the desired frequency modulation (FM) at the output of the laser. More particularly, in one embodiment of the present invention, there is provided (i) a chirp managed laser comprising an FM source, and (ii) an optical spectrum reshaper (OSR) filter, wherein the desired FM is generated using intra-cavity modulation of the phase by the depletion edge translation effect.

Accordingly, there is provided a fiber optic communication transmitter comprising:

(a) an optical signal source comprising a laser cavity and adapted to receive a base signal and generate a first signal, wherein the first signal is frequency modulated; and

(b) an optical spectrum reshaper (OSR) adapted to reshape the first signal into a second signal, wherein the second signal is amplitude modulated and frequency modulated;

(c) wherein the first signal is modulated in the laser cavity using the depletion edge translation effect.

Such transmitters can include an optical signal source that comprises a phase section with a predetermined doping profile, and modulation of the first signal comprises application of electrical field to the phase section to change refractive index of the phase section by modulating free carrier density in the phase section. The phase section can comprise a P-n-N vertical structure, or more particularly if desired a P doped InP-N doped InGaAsP quaternary-N doped InP vertical structure. The band gap of the quaternary is chosen to reduce absorption of the laser light. For example, for a laser wavelength in the range of 1550 nm, the band gap of the InGaAsP is typically 1.3 μm to 1.45 μm. Such transmitters can include a laser from one of the group consisting of (i) extended cavity distributed feedback (DFB) lasers; (ii) distributed Bragg reflector (DBR) lasers; (iii) sampled grating distributed Bragg reflector (SG-DBR) lasers; and (iv) modulated grating Y branch DBR lasers. They can also include a transmitter wherein the laser comprises one from the group consisting of, (i) external cavity lasers such as external cavity lasers with fiber Bragg gratings, ring resonators, planar lightwave circuit (PLC) Bragg gratings, arrayed waveguide gratings (AWG), and grating filters as external cavities; (ii) vertical cavity surface emitting lasers (VCSEL); and (iii) Fabry Perot lasers.

There is also provided a method for transmitting a signal, comprising:

(a) in an optical signal source comprising a laser cavity, receiving a base signal and generating a first signal, wherein the first signal is frequency modulated;

(b) reshaping the first signal into a second signal in an optical spectrum reshaper, wherein the second signal is amplitude modulated and frequency modulated;

(c) modulating the first signal in the laser cavity using the depletion edge translation effect.

Such methods can include a structure wherein the optical signal source comprises a phase section and the step of modulation of the first signal comprises applying a predetermined doping profile to the phase section and applying an electrical field to the phase section. They can also include a structure wherein the optical signal source comprises a phase section with a P-n-N vertical structure and the step of modulation of the first signal comprises applying a predetermined doping profile to the phase section and applying an electrical field to the phase section. They can also include a structure wherein the optical signal source comprises a phase section with a P doped InP-N doped InGaAsP quaternary-N doped InP vertical structure with band gap of quaternary ranging from 1.3 μm to 1.45 μm and the step of modulation of the first signal comprises applying a predetermined doping profile to the phase section and applying an electrical field to the phase section.

Such methods can also further comprise optimizing the structure and composition of the laser cavity to take advantage of linear electrooptical effects and electrorefractive effects from the electrical field and modulating the first signal in the laser cavity by applying an electrical field to take advantage of said effects.

Additionally, such methods can comprise modulating wherein the electrical field is applied by applying a negative bias voltage or negative bias voltage or both.

There is also provided a method for transmitting a signal, comprising:

(a) in an optical signal source comprising a laser cavity and a phase section having a P-n-N vertical structure, receiving a base signal and generating a first signal, wherein the first signal is frequency modulated;

(b) reshaping the first signal into a second signal in an optical spectrum reshaper, wherein the second signal is amplitude modulated and frequency modulated;

(c) applying a predetermined doping profile to at least a portion of the phase section;

(d) modulating the first signal in the laser cavity by applying an electrical field to the phase section to take advantage of edge translation effects resulting from the doping profile and the electrical field.

Such methods can also comprise optimizing the structure and composition of the laser cavity to take advantage of linear electrooptical effects and electrorefractive effects from the electrical field and modulating the first signal in the laser cavity by applying an electrical field to take advantage of said effects.

Such methods can also comprise modulating wherein the electrical field is applied by applying a negative bias voltage or positive bias voltage or both to the phase section or as otherwise desired.

### BRIEF DESCRIPTION OF THE DRAWINGS

FIG. 1 is a schematic of an exemplary chirp managed laser.

FIG. 2 is a schematic diagram showing a distributed Bragg reflector (DBR) laser cavity in accordance with one embodiment of the present invention.

FIG. 3 shows an example of a distributed feedback (DFB) laser with intra-cavity phase modulation.

FIG. 4 shows the small signal response of intra-cavity phase modulation.

FIG. 5 shows a vertically integrated twin-guide DFB laser with sampled gratings

FIG. 6 shows the vertical structure of the phase modulation section in accordance with one embodiment of the present invention.

FIG. 7 shows the orientation of the laser growth, electrical field, and crystal plane in one embodiment of the present invention.

FIG. 8 shows a mode profile and refractive index profile for Example 1 (which relates to an embodiment of the present invention).

FIG. 9 shows a doping profile and electrical field profile for n-doping level of 2*10¹⁷ cm⁻³ for Example 1.

FIG. 10 shows a plot of depletion depth versus applied voltage for the doping profile of FIG. 9.

FIG. 11 shows a plot of refractive index change versus bias voltage for the doping profile of FIG. 9.

FIG. 12A shows a plot of frequency shift versus bias voltage expected with a phase modulation section length of 20% of the laser cavity length for the doping profile of FIG. 9 and for a laser chirp factor of 0.

FIG. 12B shows a plot of frequency shift versus bias voltage expected with a phase modulation section length of 20% of the laser cavity length for the doping profile of FIG. 9 and for a laser chirp factor of 4.

FIG. 13 shows a plot of refractive index change versus doping level in the phase modulation section for Example 1.

FIG. 14A shows a plot of laser frequency shift from 0.9V to −1.5V for a phase modulation section length of 20% of the laser cavity length for Example 1 for chirp factor of 0.

FIG. 14B shows a plot of laser frequency shift from 0.9V to −1.5V for a phase modulation section length of 20% of the laser cavity length for Example 1 for chirp factor of 4.

FIG. 15 shows a plot of capacitance versus doping level at −0.3V bias for a phase modulation section of 2 um wide and 200 um long for Example 1.

### DETAILED DESCRIPTION

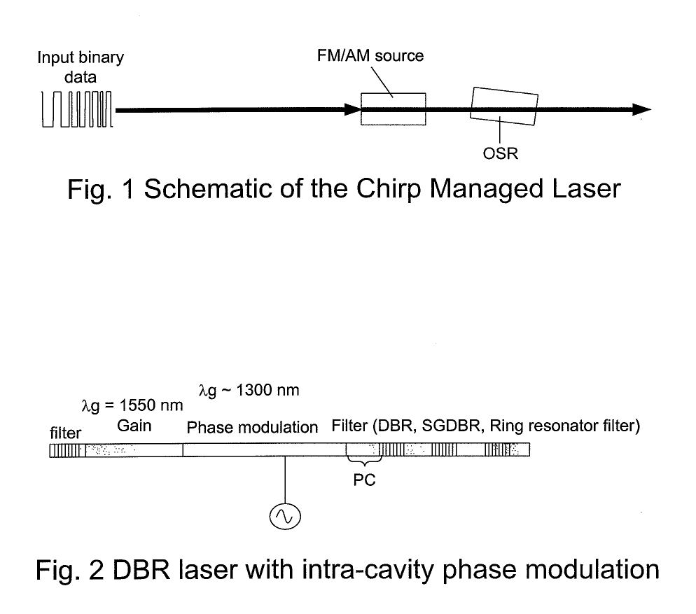

FIG. 1 is a schematic of an exemplary chirp modulated laser (“CML”) that may be used in conjunction with the present invention. In some embodiments, the frequency modulated source of the CML may comprise a directly modulated laser (DML). The optical spectrum reshaper (OSR), sometimes referred to as a frequency discriminator, can be formed by an appropriate optical element that has a wavelength-dependent transmission function, e.g., a filter. Such lasers and OSR's are disclosed in references cited above, which are incorporated by this reference. Preferably, a digital signal modulates the laser to generate frequency modulation, where the magnitude of the frequency modulation, or chirp, is chosen to be between 25% to 75% of the bit rate frequency in order to increase the reach of the transmitter in dispersive optical fiber: As one nonlimiting example, Chirp˜2.5 GHz to 7.5 GHz for a 10 Gb/s bit rate.

FIG. 2 is a schematic of a DBR laser cavity in accordance with one embodiment of the present invention. As shown, an intra-cavity phase modulation section forms part of or is coupled to the DBR laser cavity. A key characteristic of the phase modulation section is that its band gap is preferably chosen so as to minimize optical absorption at the laser wavelength. The band gap of the gain section, however, is also preferably at or near the lasing wavelength. In accordance with one embodiment of the present invention, for a laser at 1550 nm, the phase modulation section band gap is in the range of 1300 nm to 1390 nm.

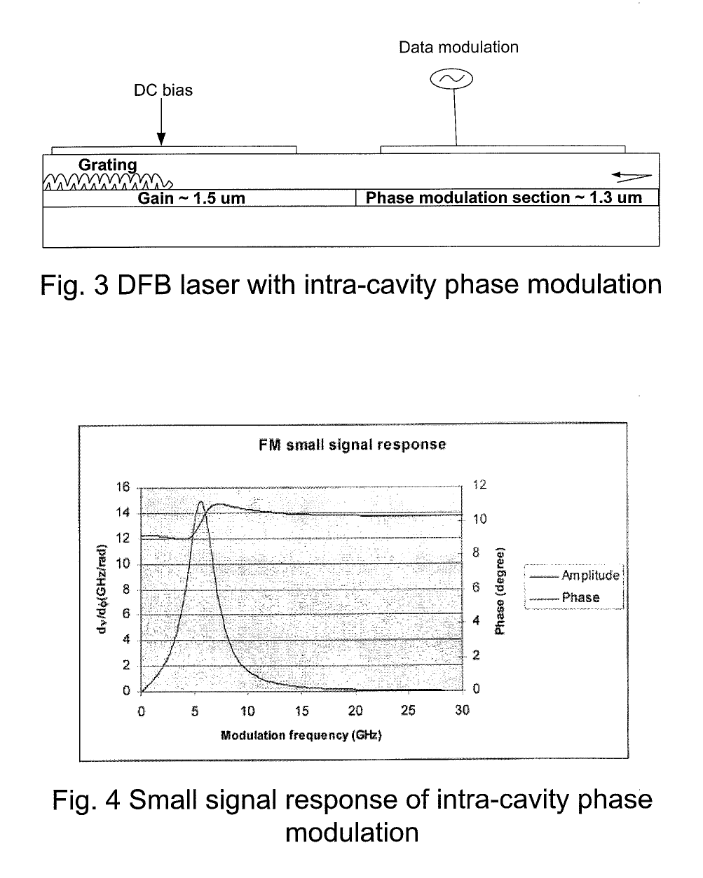

FIG. 3 shows the relationship between the gain section and phase modulation section of such an embodiment of the present invention. When the phase modulation section is modulated with a sinusoidal wave of a particular frequency, the FM of the laser is expressed as:

$$\begin{matrix}Δ v ( f ) = \frac{c}{2 π n {L}_{c}} ( - \frac{{α}_{g}}{{α}_{P}} H ( f ) + 1 ) Δ φ ( f ) & ( eq . 1 ) \\ H ( f ) = \frac{{f}_{r}^{2}}{{f}_{r}^{2} - {f}^{2} + \frac{jγ f}{2 π}} , & ( eq . 2 )\end{matrix}$$

where f is the wave frequency, c is the speed of the light, L_{c} is the effective cavity length, n is the effective refractive index of the laser, α_{g} is the chirp factor of the gain material, α_{P} is the chirp factor of the phase modulation section, fᵣ is the relaxation oscillation frequency of the laser, and γ is the damping factor of the laser.

It can be seen from Equation 1, that if the chirp factor of the loss section (α_{P}) is greater than the chirp factor of gain material (α_{g}), flat FM response can be achieved from very low frequency up to beyond relaxation oscillation frequency. FIG. 4 shows the FM response of one embodiment of the present invention using the following parameters: α_{P}=40, α_{g}=4, L_{c}=1 mm, n=3.5, fᵣ=6 GHz, and γ=20 GHz. For example, from FIG. 4, to provide 6 GHz of chirp, which is the typical required chirp for a 10 Gb/s CML, the required phase change in phase section for the 1 mm long chip is ˜0.5 rod. The FSR of the laser in this example is 43 GHz.

A self-consistent theory provided by A. E. Siegman, Lasers, University Science Books, Mill Valley, Calif., 1986, which is incorporated herein by this reference, shows that the ultimate modulation speed is defined by the free spectrum range (FSR) of the laser.

According to the Siegman theory the impulse response of intra-cavity phase modulation as a function of modulation frequency, Ω, is given by:

$$\overline{ω} ( Ω ) = \frac{2 π l τ}{L} \frac{1}{sin c ( Ω / 2 {v}_{c} )} exp ( - iΩ / 2 {v}_{c} - iπ / 2 ) , \qquad ( eq . 3 )$$

where τ is the finite response time of the phase modulator section, L is the total length of the laser cavity, l is the length of the phase section, and ν_{c} is the FSR of the laser determined by cavity length. For the case of a L=1 mm long cavity, FSR˜43 GHz, and assuming a maximum frequency Ω˜10 GHz, the argument ˜0.12 is small enough that the sinc function in equation 3 can be approximated by 1 with 0.2% error for the next higher order term. The impulse response of the chirp can then be approximated by:

$$\overline{ω} ( Ω ) = \frac{- 2 π il τ}{L} ( 1 - iΩ / 2 {v}_{c} ) \qquad ( eq . 4 )$$

Neglecting the overall π/2 phase shift, it can be seen that the second term in equation 4 is a transient chirp with π/2 phase shift relative to the first term, which is the desirable adiabatic chirp. Note that a standard distributed feedback laser provides both adiabatic and transient chirp as well, but in the case of the DFB there is an accompanying amplitude modulation. In addition the frequency response of the chirp of a directly modulated DFB is limited by the laser relaxation oscillation frequency, fr, as given by Eq. 2. Note that fᵣ is 10-14 GHz typically in a DFB laser but that it can be reduced significantly in a tunable laser due to the reduction in longitudinal confinement factor, the ratio of gain section to the sum of gain and passive sections. In contrast, the frequency response of an in-cavity phase modulated laser is independent of the relaxation oscillation frequency.

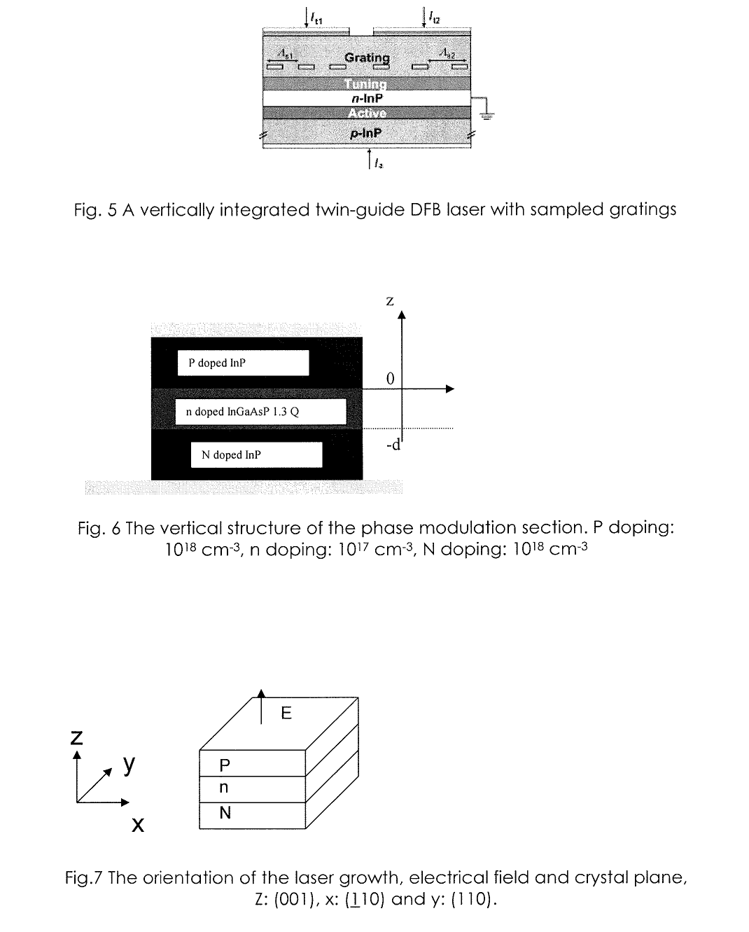

This analysis shows that the FM efficiency is proportional to the ratio of the length of the phase modulation section to the length of the laser cavity l/L. Thus, a small cavity and a large phase modulation section are generally desirable. Most lasers in use conventionally are so-called longitudinally integrated devices in which the gain, phase modulation and grating sections form a horizontal chain, as shown in FIGS. 1-3. In these lasers, the ratio of phase to cavity length is always less than one. In a different class of lasers called vertically integrated devices, the gain, grating and phase modulation sections are stacked vertically on top of each other. One such laser is a tunable twin-guide distributed feedback (DFB) laser as shown in FIG. 5.

It is an object of one particular embodiment of the present invention to directly modulate the phase modulation section of a twin-guide DFB laser to generate FM. In this embodiment of the present invention, the phase modulation section has the same length as the laser cavity, so modulation efficiency is maximized from this respect.

To obtain flat FM response as a function of modulation frequency, it is advantageous to design the phase modulation section with high phase modulation efficiency and high chirp factor phase modulation.

Another object of some embodiments of the present invention to provide for a mechanism to generate a phase shift in the phase section of an in-cavity phase modulated laser for the chirp managed laser application by application of a modulating voltage. In a standard III-V bulk semiconductor waveguide phase modulator, the refractive index changes with bias voltage mainly due to electric field related effects, such as the Pockels effect and the Kerr effect. The phase modulator has a P-i-N doping structure, where the doping level in the waveguide is generally low (<10¹⁶ cm⁻³). The P-i-N structure waveguide is reverse biased to provide a static electric field across the bulk material that modulates the refractive index.

The Pockels effect is also known as the linear electro-optical effect. This effect is related to the biaxial birefringence induced by the presence of an electric field and is exhibited by III-V semiconductors, such as InP and InGaAsP. FIG. 7 shows the orientation of laser growth, electrical field, and crystal plane for the device of FIG. 6. For conventional growth, light propagates along the (110) crystallographic axis of the phase modulator material (in the x direction in FIG. 7), and optical electrical field along the (110) crystallographic axis (y direction in FIG. 7) for transverse electric (TE) mode. For non-conventional growth, light propagates along the (110) axis and optical electrical field along the (110) axis for TE mode. The epi-layer of lasers is generally grown along the (001) axis (z direction in FIG. 7). When an electrical field is applied along z direction (forward bias in FIG. 7), the refractive index for the optical electrical field along x and y will have the values:

$$\begin{matrix}{n}_{x} = {n}_{0} + \frac{{n}_{0}^{3}}{2} {r}_{41} E & ( eq . 5 ) \\ {n}_{y} = {n}_{0} - \frac{{n}_{0}^{3}}{2} {r}_{41} E . & ( eq . 6 )\end{matrix}$$

Here r₄₁ is the linear electro-optic coefficient, E is the applied static electric field, and n₀ is refractive index. Conventionally, the light propagates along the (110) axis (x direction in FIG. 7), and for TE mode, the optical electrical field is along the (110) axis (y direction in FIG. 7), and the refractive index will decrease if reverse bias is applied. While for the non-conventional growth, the light propagates along the (110) axis, and the optical electrical field is along the (110) axis, thus when reverse bias is applied, the refractive index will increase.

The Kerr effect is also known as Franz-Keldysh effect. It is an electrorefractive effect due to tilt of the band edge by the applied electrical field. For wavelengths below the band gap of the waveguide material, the refractive index change is proportional to the square of electrical field applied, as shown in Equation 7.

$$dn ( λ , E ) = \frac{{n}_{0}^{3}}{2} {R}_{Kerr} ( λ ) {E}^{2} \qquad ( eq . 7 )$$

### For InGaAsP,

R_{Kerr}=1.5×10⁻¹⁵ exp(−8.85ΔE)cm²/V²,

where ΔE is the difference (in eV) between the photon energy of the light and the band gap of the quaternary material.

Significant improvement of the phase modulation efficiency can be obtained by proper doping profile of the waveguide. One such type of structure is called P-n-N structure. FIG. 6 shows a conventional P-n-N doping structure. With the P-n-N structure, in addition to the field related effects, two carrier related effects contribute to the refractive index change, as disclosed in, for example, J. G. Mendoza-Alvarez, et al., “Analysis of Depletion Edge Translation Lightwave Modulators,” Journal of Lightwave Technology, Vol. 6, No. 6, June 1988, pp. 793-808, which is incorporated by reference. These carrier related affects are plasma Effect and band-filling effect which are also known collectively as the depletion edge effect.

Plasma effect and band-filling effect are well known carrier related effects. The plasma effect is due to the free carrier absorption-induced refractive index change. The band-filling effect is due to the change of the Fermi level resulting from the change of carrier density, which in turn will produce a shift of the absorption edge and a change of refractive index.

When reverse electrical field is applied to the PN junction, the depletion depth will increase, the carrier in the depletion region is removed by the electrical field, and change of the refractive index is induced. In both cases, the refractive index change is proportional to removal of the free carrier, thus the doping level. For n doped InGaAsP with 1.3 um Q and light at 1.55 um, the change of the refractive index is expressed in equations 8 and 9 below:

dnₚₗₐₛₘₐ=3.61×10⁻²¹n (eq. 8)

dn_{bandfilling}=18×10⁻²¹n. (eq. 9)

When combining the electrical field distribution, depletion region, and optical mode profile, the effective refractive index change is expressed as equation 11 for conventional growth and equation 12 for non-conventional growth. Conventional growth and non-conventional growth is shown in FIG. 7. Equations 10.1-10.4 describe the index change produced by the electro-optic effect (10.1), Kerr effect (10.2), plasma effect (10.3), and band filling effect (10.4):

$$\begin{matrix}{dn}_{LEO} = \frac{{\int }_{- ∞}^{+ ∞} \frac{1}{2} {n}^{3} {r}_{41} E ( z ) {\vert u ( z ) \vert}^{2} d z}{{\int }_{- ∞}^{+ ∞} {\vert u ( z ) \vert}^{2} d z} & ( eq . 10.1 ) \\ {dn}_{Kerr} = \frac{\begin{matrix}{\int }_{0}^{+ ∞} {n}^{3} {R}_{InP} {\vert E ( z ) \vert}^{2} {\vert u ( z ) \vert}^{2} d z + \\ {\int }_{- ∞}^{0} \frac{1}{2} {n}^{3} {R}_{InGaAsP} {\vert E ( z ) \vert}^{2} {\vert u ( z ) \vert}^{2} d z\end{matrix}}{{\int }_{- ∞}^{+ ∞} {\vert u ( z ) \vert}^{2} d z} & ( eq . 10.2 ) \\ {dn}_{Plasma} = 3.61 \times {10}^{- 21} ( {cm}^{3} ) \frac{{\int }_{- {x}_{n}}^{0} {\vert u ( z ) \vert}^{2} d z}{{\int }_{- ∞}^{+ ∞} {\vert u ( z ) \vert}^{2} d z} & ( eq . 10.3 ) \\ {dn}_{Bandfilling} = 18 \times {10}^{- 21} ( {cm}^{3} ) \frac{{\int }_{- {x}_{n}}^{0} {\vert u ( z ) \vert}^{2} d z}{{\int }_{- ∞}^{+ ∞} {\vert u ( z ) \vert}^{2} d z} N & ( eq . 10.4 )\end{matrix}$$

Here u(z) is the envelope of the optical electric field, and E(z) is the static applied electric field. For conventional growth:

dn=—dn_{LEO}+dn_{Kerr}+dn_{Plasma}+dn_{bandfilling} (eq. 11)

For non conventional growth:

dn=dn_{LEO}+dn_{Kerr}+dn_{Plasma}+dn_{bandfilling} (eq. 12)

It is an object of certain embodiments of the present invention to construct a modulator which has an optimum doping profile for the generation of high efficiency frequency modulation using the depletion edge effect. As it has been described above, phase modulation inside phase modulator section of the cavity of a laser leads to frequency modulation of the output of the laser. FM efficiency is defined as the frequency shift generated by an applied voltage divided by the amplitude of the applied voltage. Here are provided a number of examples of doping profiles that produce high FM efficiency in-cavity phase modulated lasers. One example of such modulator is a P-n-N waveguide as shown in FIG. 6: The P-doping level of P-layer InP is 10¹⁸ cm⁻³, the N-doping level of N-layer InP is 10¹⁸ cm⁻³, and the thickness of the waveguide is set as 0.3 um. The doping profile is chosen to increase the magnitude of the static space charge field and to increase the overlap integral between the optical mode and the static electric space charge field.

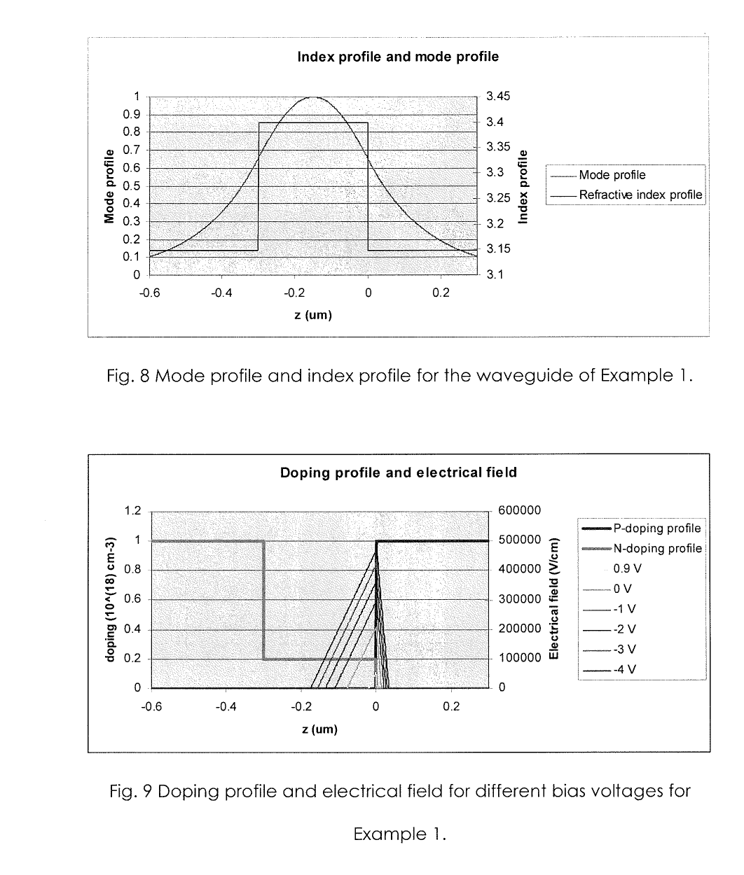

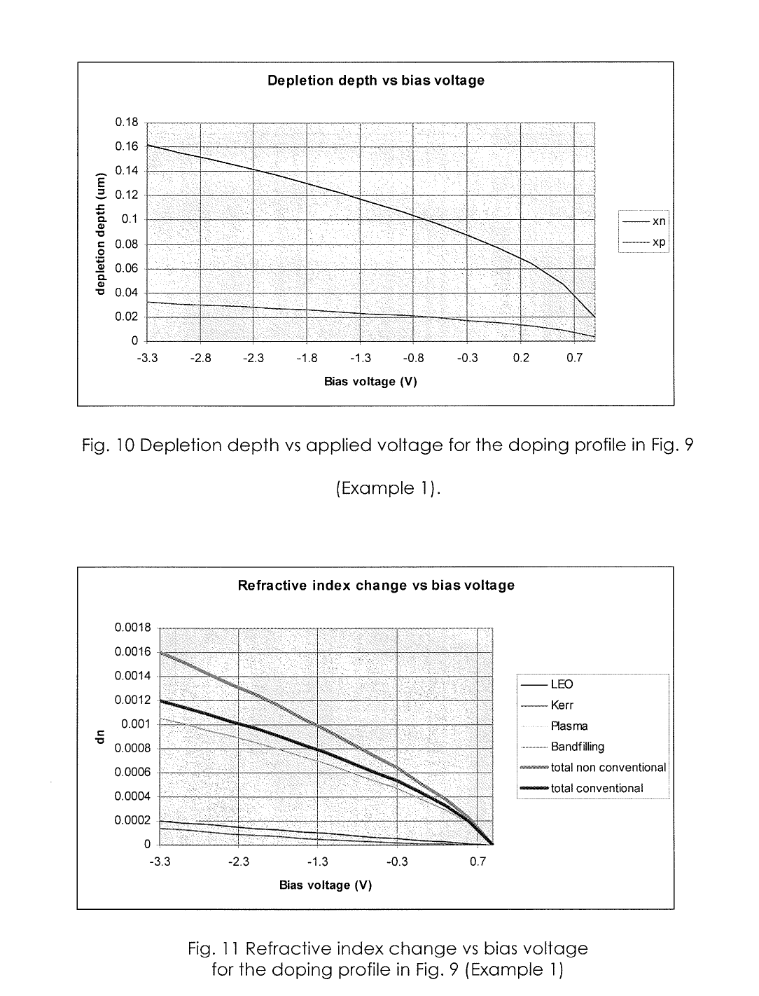

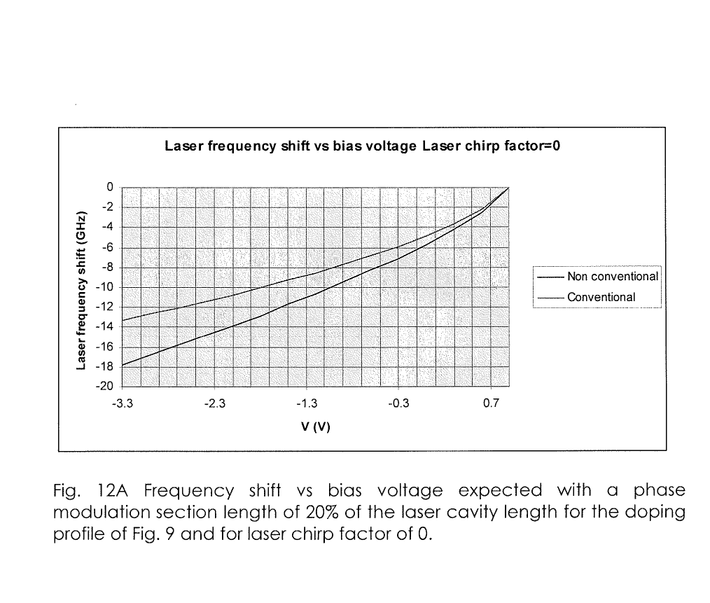

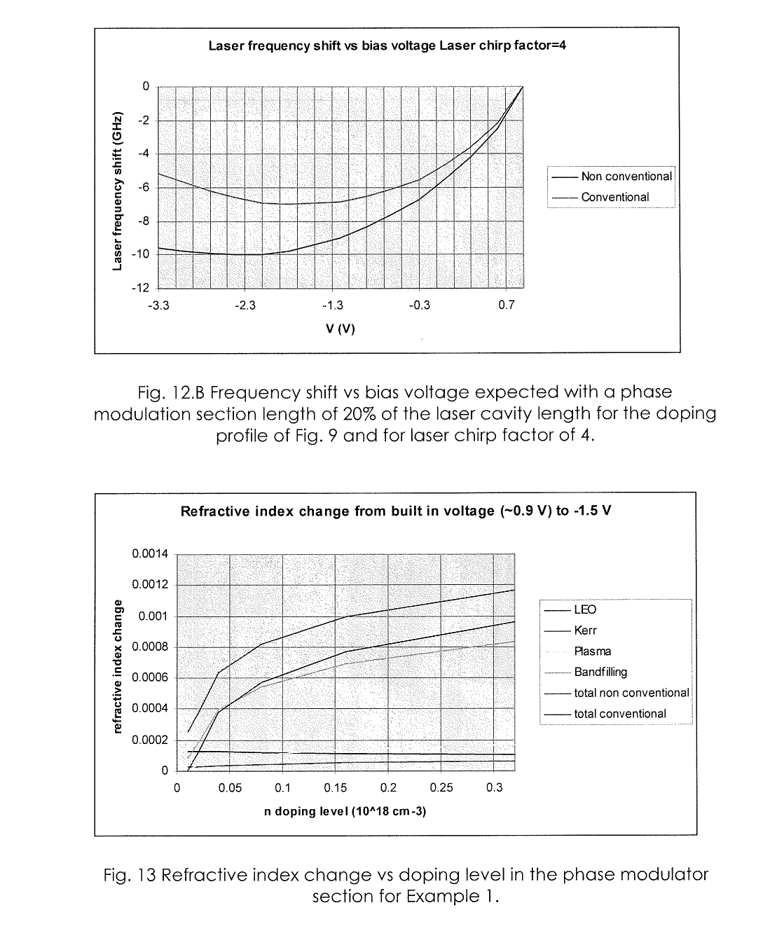

FIG. 8 shows the mode profile and refractive index profile of this waveguide and FIG. 9 shows the doping profile and electrical field for n-doping level of n=2*10¹⁷ cm⁻³ in this waveguide. Note that light doping of the normally intrinsic region, i.e. region sandwiched between the heavily P doped and heavily N doped regions, increases the peak space charge field and its overlap with the optical mode. FIG. 10 shows the depletion depth vs. applied voltage for the profile of FIG. 9. FIG. 11 shows a plot of refractive index change versus bias voltage for the doping profile of FIG. 9. According to one embodiment of the present invention, the normally intrinsic region of the diode can be lightly n doped in order to increase the FM efficiency.

FIGS. 12A and 12B show plots of frequency shift versus bias voltage expected with a phase modulation section length of 20% of the laser cavity length for the doping profile of FIG. 9 and for a laser chirp factor of 0 and 4, respectively. Note that FM efficiency is determined by the slope of the frequency shift versus voltage. In this case, as shown in FIGS. 12A and 12B, the slope of the curves is larger near slightly forward biased voltage. As the reverse biased voltage increases, the depletion width increases and saturates. This is because there is a finite density of free carriers that move to form the space charge field. The optimum FM efficiency can therefore be at a point where the modulator is slightly forward biased. However, the forward bias voltage is below the threshold voltage at which point the bands are flat and a forward current flows.

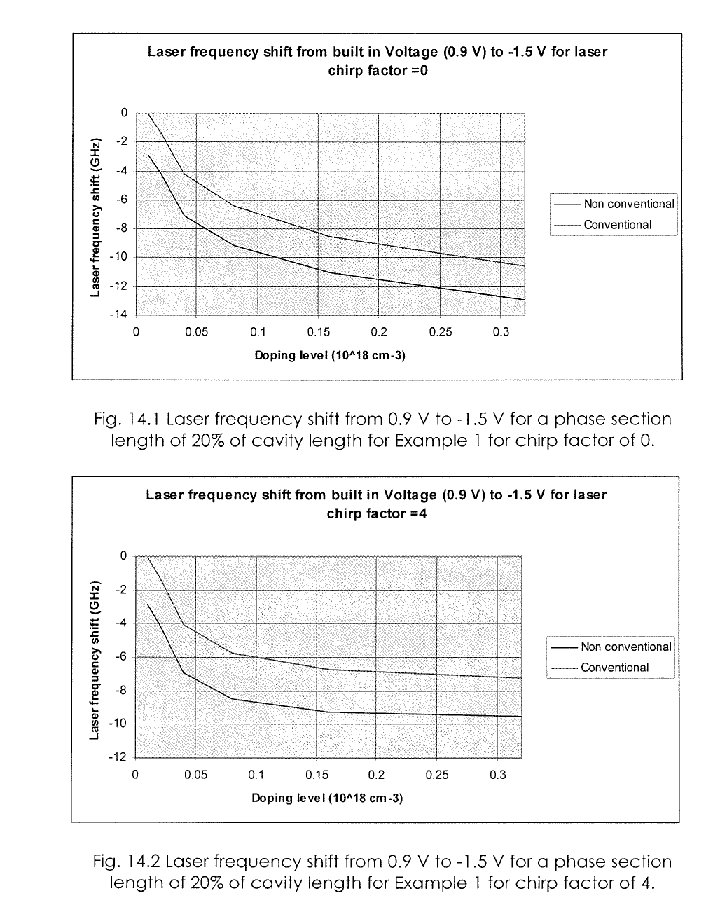

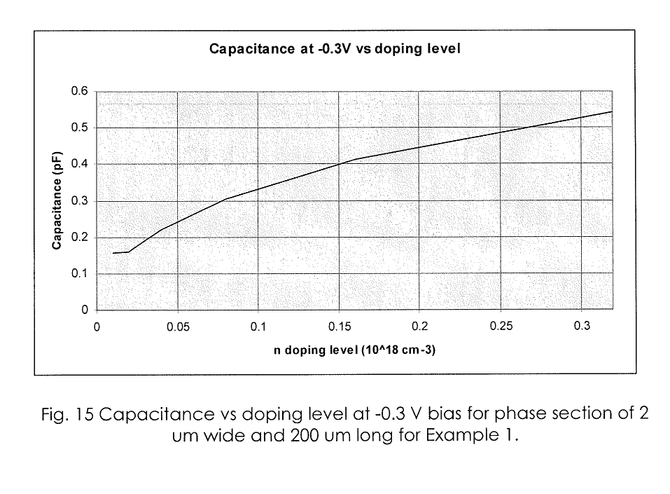

The equations above yield refractive index change as a function of the n doping level in the normally intrinsic region of the diode; i.e. density of the region n in the P-n-N profile. FIG. 13 shows a plot of refractive index change versus doping level in the phase modulation section for Example 1. Using this result, FIGS. 14A and 14B show plots of laser frequency shift from 0.9V to −1.5V for a phase modulation section length of 20% of the laser cavity length for Example 1 for chirp factor of 0 and 4, respectively. Note that the frequency shift becomes relatively insensitive to the doping level as the doping is increased above 3×10¹⁷ cm⁻³. FIG. 15 shows a plot of capacitance versus doping level at −0.3V bias for a phase modulation section of 2 um wide and 200 um long for Example 1. Note that the higher the doping level, the higher the laser frequency shift, thus the laser chirp under modulation, and that the capacitance increases with the doping level in this plot. The optimum doping level should also preferably consider the capacitance. A large capacitance can decrease the modulation bandwidth and limit operation at high modulation frequencies.

The foregoing description of the embodiments of the invention has been presented for purposes of illustration and description and is not intended to be exhaustive or to limit the invention to the precise forms disclosed. Numerous modifications and adaptations are apparent to those skilled in the art without departing from the spirit or scope of the invention.

What is claimed is:

1. A fiber optic communication transmitter comprising:
(a) an optical signal source comprising a laser cavity and adapted to receive a base signal and generate a first signal, wherein the first signal is frequency modulated; and
(b) an optical spectrum reshaper (OSR) adapted to reshape the first signal into a second signal, wherein the second signal is amplitude modulated and frequency modulated;
(c) wherein the first signal is modulated in the laser cavity using the depletion edge translation effect.

2. A transmitter according to claim 1 wherein the optical signal source comprises a phase section with a predetermined doping profile, and modulation of the first signal comprises application of electrical field to the phase section to change refractive index of the phase section by modulating free carrier density in the phase section.

3. A transmitter according to claim 2 wherein the phase section comprises a P-n-N vertical structure.

4. A transmitter according to claim 3 wherein the phase section comprises a P doped InP-n doped InGaAsP 1.3 Q-N doped InP vertical structure.

5. A transmitter according to claim 3 wherein an optical waveguide is created along the (110) crystallographic axis of phase modulator material of the phase section, and an optical electrical field is created along the (−110) direction of the crystallographic axis of the phase modulator material of the phase section.

6. A transmitter according to claim 3 wherein the n region is doped at a density that is less than the doping density of the P region or doping density of the N region.

7. A transmitter according to claim 6 wherein the n region is doped at a density of about 10¹⁷ cm⁻³, and the N and P regions are doped at a density of about 10¹⁸ cm⁻³.

8. A transmitter according to claim 3 wherein the phase section is forward biased at a voltage below a diode threshold value of the phase section.

9. A transmitter according to claim 1 wherein the laser comprises one from the group consisting of (i) distributed feedback (DFB) lasers; (ii) distributed Bragg reflector (DBR) lasers; (iii) sampled grating distributed Bragg reflector (SG-DBR) lasers; and (iv) Y branch DBR lasers.

10. A transmitter according to claim 1 wherein the laser comprises one from the group consisting of, (i) external cavity lasers such as external cavity lasers with fiber Bragg gratings, ring resonators, planar lightwave circuit (PLC) Bragg gratings, arrayed waveguide gratings (AWG), and grating filters as external cavities; (ii) vertical cavity surface emitting lasers (VCSEL); and (iii) Fabry Perot lasers.

11. A method for transmitting a signal, comprising:
(a) in an optical signal source comprising a laser cavity, receiving a base signal and generating a first signal, wherein the first signal is frequency modulated;
(b) reshaping the first signal into a second signal in an optical spectrum reshaper, wherein the second signal is amplitude modulated and frequency modulated;
(c) modulating the first signal in the laser cavity using the depletion edge translation effect.

12. A method according to claim 11 wherein the optical signal source comprises a phase section and modulation of the first signal comprises applying a predetermined doping profile to the phase section and applying an electrical field to the phase section.

13. A method according to claim 11 wherein the optical signal source comprises a phase section with a P-n-N vertical structure and modulation of the first signal comprises applying a predetermined doping profile to the phase section and applying an electrical field to the phase section.

14. A method according to claim 11 wherein the optical signal source comprises a phase section with a P doped InP-n doped InGaAsP 1.3 Q-N doped InP vertical structure and modulation of the first signal comprises applying a predetermined doping profile to the phase section and applying an electrical field to the phase section.

15. A method according to claim 13 further comprising creating an optical waveguide along the (110) crystallographic axis of phase modulator material of the phase section, and creating an optical electrical field along the (−110) direction of the crystallographic axis of the phase modulator material of the phase section.

16. A method according to claim 13 further comprising doping the n region of the phase section at a density that is less than the doping density of the P region of the phase section or doping density of the N region of the phase section.

17. A method according to claim 16 further comprising doping the n region of the phase section at a density of about 10¹⁷ cm⁻³, and doping the N and P regions of the phase section at a density of about 10¹⁸ cm⁻³.

18. A method according to claim 13 further comprising apply a forward bias voltage to the phase section below a diode threshold value of the phase section.

19. A method according to claim 11 further comprising optimizing the structure and composition of the laser cavity to take advantage of linear electrooptical effects and electrorefractive effects from the electrical field and modulating the first signal in the laser cavity by applying an electrical field to take advantage of said effects.

20. A method according to claim 11 wherein the electrical field is applied by applying a negative bias voltage to the phase section.

21. A method according to claim 11 wherein the electrical field is applied by applying a positive bias voltage to the phase section.

22. A method for transmitting a signal, comprising:
(a) in an optical signal source comprising a laser cavity and a phase section having a P-n-N vertical structure, receiving a base signal and generating a first signal, wherein the first signal is frequency modulated;
(b) reshaping the first signal into a second signal in an optical spectrum reshaper, wherein the second signal is amplitude modulated and frequency modulated;
(c) applying a predetermined doping profile to at least a portion of the phase section;
(d) modulating the first signal in the laser cavity by applying an electrical field to the phase section to take advantage of edge translation effects resulting from the doping profile and the electrical field.

23. A method according to claim 22 further comprising optimizing the structure and composition of the laser cavity to take advantage of linear electrooptical effects and electrorefractive effects from the electrical field and modulating the first signal in the laser cavity by applying an electrical field to take advantage of said effects.

24. A method according to claim 22 wherein the electrical field is applied by applying a negative bias voltage to the phase section.

25. A method according to claim 22 wherein the electrical field is applied by applying a positive bias voltage to the phase section.

26. A method according to claim 22 further comprising creating an optical waveguide along the (110) crystallographic axis of phase modulator material of the phase section, and creating an optical electrical field along the (−110) direction of the crystallographic axis of the phase modulator material of the phase section.

27. A method according to claim 22 further comprising doping the n region of the phase section at a density that is less than the doping density of the P region of the phase section or the doping density of the N region of the phase section.

28. A method according to claim 27 further comprising doping the n region of the phase section at a density of about 10¹⁷ cm⁻³, and doping the N and P regions of the phase section at a density of about 10¹⁸ cm⁻³.

29. A method according to claim 22 further comprising apply a forward bias voltage to the phase section below a diode threshold value of the phase section.
